(19) United States
(12) Patent Application Publication
(10) Pub. No.: US 2011/0120760 A1
(43) Pub. Date: May 26, 2011

(54) ELECTROLESS COPPER PLATING METHOD, PRINTED WIRING BOARD, METHOD FOR PRODUCING THE SAME, AND SEMICONDUCTOR DEVICE

(76) Inventors: Ryoichi Okada, Tokyo (JP); Teppei Ito, Tokyo (JP)

(21) Appl. No.: 13/055,960

(22) PCT Filed: Jul. 17, 2009
(86) PCT No.: PCT/JP2009/062979

§ 371 Date: Jan. 26, 2011

(30) Foreign Application Priority Data
Jul. 30, 2008 (JP) 2008195747

(51) Int. Cl. H05K 1/09; H05K 3/02

(52) U.S. Cl. 174/257; 427/97.2; 216/17

(57) ABSTRACT

The present invention is to provide a printed wiring board having a fine wiring formed on a resin base material by the semi-additive method, and is also to provide an electroless copper plating method capable of producing the printed wiring board, a method for producing a printed wiring board using the electroless copper plating method, a printed wiring board produced by the production method, and a semiconductor device provided with the printed wiring board. An electroless copper plating method comprising the step of performing acid treatment before an electroless copper plating step including cleaner, providing palladium catalyst, palladium reduction, and electroless copper plating process, a method for producing a printed wiring board using the electroless copper plating method, a printed wiring board produced by the method for producing the printed wiring board, and a semiconductor device provided with the printed wiring board.

### TECHNICAL FIELD

The present invention relates to an electroless copper plating method, a printed wiring board, a method for producing the same, and a semiconductor device.

### BACKGROUND ART

In recent years, with growing demand of diversification, miniaturization and decrease in layer thickness of electronic components, electronics and so on, multilayer printed wiring boards used for the electronic components, electronics and so on are required to be miniaturized and to decrease the layer thickness. Hence, development of multilayer printed wiring boards having various structures is encouraged.

Generally, a multilayer printed wiring board is produced by alternately laminating circuits and insulating layers. Specifically, for example, there is a method comprising the steps of: forming a circuit by etching a copper-clad laminate by a subtractive method or the like; laminating an insulating layer on the circuit; forming another circuit on the surface of the insulating layer; and laminating another insulating layer on the circuit (for example, Patent Literature 1).

In addition, by using a thin copper foil having a thickness of 5 μm or less as a copper foil of the copper-clad laminate, it has been possible to allow finer wiring of a multilayer printed wiring board.

However, due to growing demand of finer wiring in recent years, the buildup process by the semi-additive method receives attention. The process comprises the following steps. Firstly, a resin surface is roughened by desmear treatment, and an electroless copper plating layer is formed on the roughened surface using a palladium catalyst. Next, a photo sensitive resist layer is further formed on the copper plating layer to perform patterning through processes such as exposure and development followed by forming a circuit pattern by electrolytic copper plating. Finally, the resist is peeled and the electroless copper plating layer is removed by etching. Thus, a fine copper wiring is formed.

However, the buildup process by the semi-additive method generally uses a buildup resin film designed for the above process flow. Particularly, in the desmear process, removal of smear in laser via holes formed in a buildup layer, and roughening of the resin surface to improve the interface adhesion between the resin surface and an electroless copper, are simultaneously performed. Therefore, resins are designed to have an appropriate desmear resistance. The buildup process by the semi-additive method has an advantage in forming a fine wiring as described above, however, there is a disadvantage of having many restrictions to materials.

As a method for forming a good metal layer on a resin base material, the resin base material is generally roughened. That is, by roughening the resin base material, the metal layer formed in the subsequent process is allowed to have the anchor effect, thus, the adhesion between the resin base material and the metal layer improves. As a method of roughening the resin base material surface, generally, there has been a proposed method comprising the steps of: compounding an inorganic filler such as calcium carbonate in a resin composition for forming the resin base material; and selectively dissolving the inorganic filler in the vicinity of the resin base material surface using an alkaline solution, for example, permanganate aqueous solution (for example, see Patent Literature 2).

However, there is a problem in the above method that if the distribution of the compounded inorganic filler becomes uneven, the roughening degree of the resin base material surface becomes uneven, and thereby, the adhesion between the resin base material and the metal layer becomes partially insufficient. Further, it is hard to roughen the resin base material surface if silica is used as the inorganic filler since the selective dissolution as described above is not applicable to silica. Furthermore, if the above process is applied to the copper-clad laminate, excessive desmear treatment is essentially not required, since the roughened shape has already been formed on the resin surface which exposes after copper foil etching.

### CITATION LIST

### Patent Literature

[Patent Literature 1] Japanese Patent Application Laid-Open (JP-A) No. 2002-305374
[Patent Literature 2] JP-A No. H11-186716

### SUMMARY OF INVENTION

### Technical Problem

The object of the present invention is to provide a printed wiring board having a fine copper wiring with high adhesion and high reliability formed by the semi-additive method on a resin surface in which copper foils of a copper-clad laminate are etched. The present invention is to provide an electroless copper plating method capable of producing the printed wiring board, a method for producing a printed wiring board using the electroless copper plating method, a printed wiring board produced by the above production method, and a semiconductor device provided with the printed wiring board.

### Solution to Problem

The above objects can be attained by the following [1] to [9].

[1] An electroless copper plating method for forming an electroless copper plating layer on a resin surface selected from a resin base material surface, an insulating resin layer surface, a through hole wall surface, a via hole bottom surface and a via hole wall surface using a palladium catalyst, wherein the surface to be plated is treated using an acid solution as pretreatment before performing alkaline degreasing, palladium adsorption, palladium reduction and electroless copper plating process.

[2] The electroless copper plating method according to the above [1], wherein the acid solution is an aqueous solution containing sulfuric acid.

[3] A method for producing a printed wiring board comprising the step of forming an electroless copper plating layer using the electroless copper plating method defined by the above [1] or [2].

[4] A method for producing a printed wiring board comprising the step of forming an electroless copper plating layer on a resin base material surface, being obtained by etching a copper foil of a copper-clad laminate and transferring a roughened shape of the copper foil, using the electroless copper plating method defined by the above [1] or [2].

[5] The method for producing the printed wiring board according to the above [3] or [4], wherein heat treatment is performed after electroless copper plating followed by electrolytic copper plating.

[6] The method for producing the printed wiring board according to the above [5], wherein a temperature of the heat treatment is 200° C. or more.

[7] The method for producing the printed wiring board according to any of the above [4] to [6], wherein a resin base material and/or an insulating resin layer of the copper-clad laminate is formed with a resin composition containing at least a cyanate ester resin and a polyfunctional epoxy resin.

[8] A printed wiring board produced by the production method defined by any of the above [3] to

[9] A semiconductor device comprising a printed wiring board defined by the above [8] and a semiconductor element mounted on the printed wiring board.

### Advantageous Effects of Invention

The printed wiring board and the method for producing the same of the present invention can secure excellent adhesion of the resin surface to the metal layer by applying a general semi-additive process after performing acid treatment on the resin surface, which is obtained by etching the copper foil of the copper-clad laminate. Further, by performing heat treatment after electrolytic copper plating, a fine wiring excellent in adhesion can be formed.

### DESCRIPTION OF EMBODIMENTS

Hereinafter, the printed wiring board and the method for producing the same of the present invention will be described in detail.

The electroless copper plating method of the present invention comprises the step of forming an electroless copper plating layer on a resin surface selected from a resin base material surface, an insulating resin layer surface, a through hole wall surface, a via hole bottom surface and a via hole wall surface, typically a resin surface obtained by etching a copper foil of a copper-clad laminate, wherein after etching the copper foil, the surface to be plated is subjected to acid treatment using an acid solution, and then, the electroless copper plating step is performed. That is, the key point of the present invention is that before performing the electroless copper plating step including alkaline degreasing, palladium adsorption, palladium reduction and electroless copper plating process on any resin surface selected from the resin base material surface exposed by etching the copper foil of the copper-clad laminate, the insulating resin layer surface laminated on an inner layer which includes a circuit on the surface of the copper-clad laminate, and further, the through hole wall surface, the via hole bottom and wall surfaces provided on a production panel of the printed wiring board, the surface to be plated is subjected to the electroless copper plating process using the acid solution.

As the acid treatment using the acid solution, sulfuric acid treatment using an aqueous solution containing sulfuric acid as the acid solution is preferable. The concentration of the sulfuric acid is preferably from 1 to 20 wt %, more preferably from 4 to 10 wt %. If the concentration of the sulfuric acid aqueous solution exceeds 50 wt %, the acidity of the acid solution is strong, thus, the yield of the printed wiring board upon production and the reliability of the printed wiring board after production tend to decrease. By having the concentration of the sulfuric acid aqueous solution of 20 wt % or less, palladium to be a catalyst upon electroless plating tends to attach on the resin surface after the acid treatment, and it is able to form an excellent electroless copper plating layer.

The sulfuric acid may contain hydroxylamine sulfate as an additive. The time of sulfuric acid treatment is not particularly limited if the throwing power and adhesion of the electroless copper plating are secured, and is preferably from 1 to 10 minutes. The acid may be hydrochloric acid, nitric acid, or organic acid besides sulfuric acid. The specific treatment method is not particularly limited as long as the surface to be plated can contact the acid solution. The examples include a method of dipping the copper-clad laminate in the acid solution.

In the present invention, “a resin surface selected from a resin base material surface, an insulating resin layer surface, a through hole wall surface, a via hole bottom surface, and a via hole wall surface” refers to at least one resin surface from the resin base material surface, the insulating resin layer surface, the through hole wall surface, the via hole bottom surface, and the via hole wall surface, and means that the object of electroless copper plating layer formation, that is, the object of the treatment by the acid solution is at least one of the above resin surfaces.

The method for producing the printed wiring board of the present invention comprises the step of forming the electroless copper plating layer by the above electroless copper plating method. Hereinafter, the method for producing the printed wiring board of the present invention will be described with a specific example.

Firstly, the copper foils of a double-sided copper-clad laminate are overall etched using a ferric chloride (Iron (II) chloride) solution or copper (II) chloride solution, thus a resin base material is obtained. That is, the resin surface of the resin base material is exposed by etching. As the roughened shape of the copper foil is transferred on the resin surface, it is possible to arrange the surface roughness of the resin base material to be obtained by the type of the copper foil of the original copper-clad laminate. The roughness of the copper foil may be arranged depending on the level of the fine wiring. To electrically connect the upper and lower sides of the substrate, through-holes and/or via-holes may be formed. A mechanical drill, laser processing, etc, may be used for forming through-holes and via-holes. The through-hole processing and via-hole processing may be performed before or after etching the copper foils.

Next, the acid treatment is performed on the resin surface of the obtained resin base material. The acid treatment may be a batch-type dipping treatment or continuous process by spraying. It is also possible to adjust the surface roughness of the resin surface, on which the roughened shape of the copper foil is transferred, by the above acid treatment (treatment using acid solution). That is, if the surface roughness of the resin surface obtained by etching is too high, it is possible to decrease the surface roughness by the acid treatment to obtain a resin surface having a surface roughness suitable for the following electroless copper plating.

After the acid treatment, water washing is performed followed by electroless copper plating. The electroless copper plating generally comprises the steps of process in a cleaner, providing palladium catalyst (palladium catalyst adsorption), palladium catalyst reduction, and electroless copper plating process. The purpose of the cleaner is to remove oil and fat content and contamination attached on the resin surface, and to let a surfactant adsorb on the resin surface in order to improve adhesive property of the palladium catalyst in the following step. Removal of the oil and fat content and contamination in the cleaner is generally performed by alkaline degreasing using alkaline aqueous solution. Following process in the cleaner, providing the palladium catalyst, the palladium catalyst reduction, and the electroless copper plating process are performed. Thereby, the electroless copper plating layer is formed on the resin base material surface.

Next, to form a circuit pattern, a photo sensitive resist pattern is formed on the resin base material surface with the electroless copper plating layer. Generally, an ultraviolet photosensitive dry film resist is laminated on the base material surface and selectively exposed using a negative film, etc., followed by development. Thus, a resist pattern is formed. Then, after a copper circuit is formed by electrolytic copper plating in the parts where the resist is removed by development, the resist is peeled off. Finally, the electroless copper plating layer is removed by etching, and thus a fine circuit pattern is formed. Thereafter, a solder resist is formed on the outermost layer, and electrode parts for connection are exposed by exposure and development so that semiconductor elements can be mounted. Then, the resultant product after nickel-gold plating process is cut into a predetermined size, thereby, a multilayer printed wiring board is obtained.

In addition, a multilayer printed wiring board, in which a conductor is further laminated, is obtained by, for example, forming an insulating resin layer on the fine circuit formed by etching the electroless copper plating layer on the copper-clad laminate, and further forming a fine circuit through forming the electroless copper plating layer, the resist pattern, and the electrolytic copper plating layer as described above.

In the method for producing the multilayer printed wiring board of the present invention, it is preferable that the copper circuit is formed by electrolytic copper plating after the electroless copper plating, and then, the substrate having the copper circuit formed is subjected to heat treatment. This is because the peeling strength of the copper plating increases. The specific temperature of the heat treatment is not particularly limited, and is preferably 150° C. or more, more preferably 180° C. or more, still more preferably 200° C. or more, while the heat treatment is performed preferably at 300° C. or less, more preferably at 270° C. or less, still more preferably at 250° C. or less, from the viewpoint of copper oxidation.

The resin base material and/or insulating resin layer of the copper-clad laminate used in the present invention, particularly, the resin base material of the copper-clad laminate is preferably formed with a resin composition containing a cyanate ester resin. Thereby, it is possible to decrease the thermal expansion coefficient of the copper-clad laminate. Further, by using the resin composition containing the cyanate ester resin, a resin base material (typically, one containing glass fiber cloth) and an insulating resin layer excellent in mechanical strength is obtained. In addition, if the resin composition contains the cyanate ester resin, the effect of acid treatment using the above acid solution is high.

The cyanate ester resin is obtained by the reaction of, for example, a cyanogen halide compound with phenol, and if necessary, the reactant is prepolymerized by heating or the like. Specific examples of the cyanate ester resin include bisphenol type cyanate resins such as novolac type cyanate resins, bisphenol A type cyanate resins, bisphenol E type cyanate resins, and tetramethyl bisphenol F type cyanate resins. Among the above, the novolac type cyanate resins are preferable. Thereby, the cross-linking density increases, and it is possible to improve the heat resistance and flame retardance of the resin base material and insulating resin layer. This is because the novolac type cyanate resin forms a triazine ring after a curing reaction.

As the novolac type cyanate resin, for example, one represented by the following Formula (I) can be used.

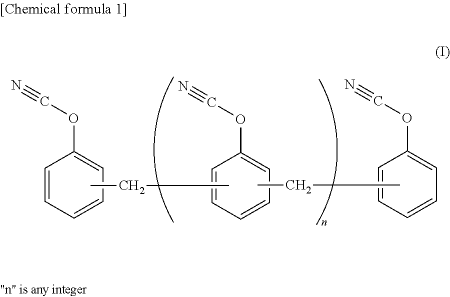

The average repeating unit “n” of the novolac type cyanate resin represented by the above Formula (I) is not particularly limited, and is preferably from 1 to 10, more preferably from 2 to 7. If the average repeating unit “n” is less than the above lower limit, the novolac type cyanate resin easily crystallizes, and the solubility to a general-purpose solvent relatively decreases, thereby, the handling may be difficult. If the average repeating unit “n” exceeds the above upper limit, the melting viscosity becomes too high, thereby, the formability of the insulating resin layer may decrease.

The weight-average molecular weight of the cyanate ester resin is not particularly limited, and is preferably from 5.0×10² to 4.5×10³, more preferably from 6.0×10² to 3.0×10³. If the weight-average molecular weight is less than the above lower limit, the mechanical strength of the cured product of the insulating resin layer may decrease, and further, the insulating resin layer formed by using the cyanate ester resin exhibits tackiness so that the transfer of the resin may be caused. In addition, if the weight-average molecular weight exceeds the above upper limit, the rate of curing reaction increases, and when the cyanate ester resin is used for the multilayer printed wiring board, forming failure may be caused, and the peeling strength between layers may decrease.

In the present invention, the weight-average molecular weight of the resin such as the cyanate ester resin, etc. can be measured by, for example, GPC (gel permeation chromatography calibrated using polystyrene as standard substance).

The cyanate ester resin including a derivative thereof can be used alone, or in combination of two or more kinds having different weight-average molecular weight. One or more kinds and prepolymers thereof can also be used in combination.

The content of the cyanate ester resin in the resin composition is not particularly limited, and is preferably from 5 to 50 wt %, more preferably from 20 to 40 wt %, with respect to the total weight of the resin composition. If the content is less than the above lower limit, the resin base material (preferably one containing glass fiber cloth) and the insulating resin layer may be difficult to be formed. If the content exceeds the above upper limit, the strength of the resin base material and insulating resin layer may decrease.

The resin composition containing the cyanate ester resin preferably contains a polyfunctional epoxy resin (substantially containing no halogen atom). Examples of the polyfunctional epoxy resin include bisphenol type epoxy resins such as bisphenol A type epoxy resins, bisphenol F type epoxy resins, bisphenol E type epoxy resins, bisphenol S type epoxy resins, bisphenol M type epoxy resins, bisphenol P type epoxy resins, and bisphenol Z type epoxy resins; novolac type epoxy resins such as phenol novolac type epoxy resins and cresol novolac epoxy resins; arylalkylene type epoxy resins such as biphenyl type epoxy resins, xylylene type epoxy resins and biphenyl aralkyl type epoxy resins; naphthalene type epoxy resins; anthracene type epoxy resins; phenoxy type epoxy resins; dicyclopentadiene type epoxy resins; norbornene type epoxy resins; adamantane type epoxy resins; and fluorene type epoxy resins.

The polyfunctional epoxy resins may be used alone, or in combination of two or more kinds having different weight-average molecular weight. One or more kinds and prepolymers thereof may also be used in combination.

Among the above, the arylalkylene type epoxy resins are particularly preferable. By using the arylalkylene type epoxy resin, the hygroscopic solder heat resistance and flame retardance of the resin base material and the insulating resin layer improve.

The arylalkylene type epoxy resin refers to an epoxy resin having one or more arylalkylene groups in the repeating unit. The examples include xylylene type epoxy resins and biphenyl dimethylene type epoxy resins. Among the above, the biphenyl dimethylene type epoxy resins are preferable. The biphenyl dimethylene type epoxy resin is represented by, for example, the following Formula (II).

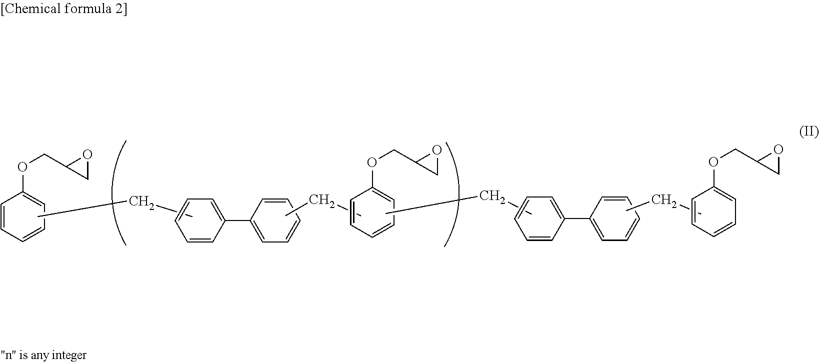

The average repeating unit “n” of the biphenyl dimethylene type epoxy resin represented by the above Formula (II) is not particularly limited, and is preferably from 1 to 10, more preferably from 2 to 5. If the average repeating unit “n” is less than the above lower limit, the biphenyl dimethylene type epoxy resin easily crystallizes, and the solubility to a general-purpose solvent relatively decreases, thereby, the handling may be difficult. If the average repeating unit “n” exceeds the above upper limit, the flowability of the resin decreases, and forming failure, etc. may be caused.

The content of the polyfunctional epoxy resin in the resin composition is not particularly limited, and is preferably from 1 to 55 wt %, more preferably from 2 to 40 wt %, with respect to the total weight of the resin composition containing the cyanate ester resin. If the content is less than the above lower limit, the reactivity of the cyanate ester resin may decrease and the humidity resistance of the product to be obtained may decrease. If the content exceeds the above upper limit, the heat resistance of the resin base material and insulating resin layer may decrease.

The weight-average molecular weight of the polyfunctional epoxy resin is not particularly limited, and is preferably from 5.0×10² to 2.0×10⁴, more preferably from 8.0×10² to 1.5×10⁴. If the weight-average molecular weight is less than the above lower limit, the resin base material (typically one containing glass fiber cloth) and the insulating resin layer may exhibit the tackiness. If the weight-average molecular weight exceeds the above upper limit, the impregnation of the resin composition into a glass base material (glass fiber cloth) decreases upon producing the resin base material (typically one containing glass fiber cloth), thereby, a uniform product may not be obtained.

The resin composition containing the cyanate ester resin preferably contains a phenol resin. Examples of the phenol resin include novolac type phenol resins, resol type phenol resins, and arylalkylene type phenol resins. They may be used alone, or in combination of two or more kinds having different weight-average molecular weight. One or more kinds and prepolymers thereof may also be used in combination. Among the above, the arylalkylene type phenol resins are particularly preferable. By using the arylalkylene type phenol resin, the hygroscopic solder heat resistance further improves.

Examples of the arylalkylene type phenol resin include xylylene type phenol resins and biphenyl dimethylene type phenol resins. The biphenyl dimethylene type phenol resin is represented by, for example, the following Formula (III).

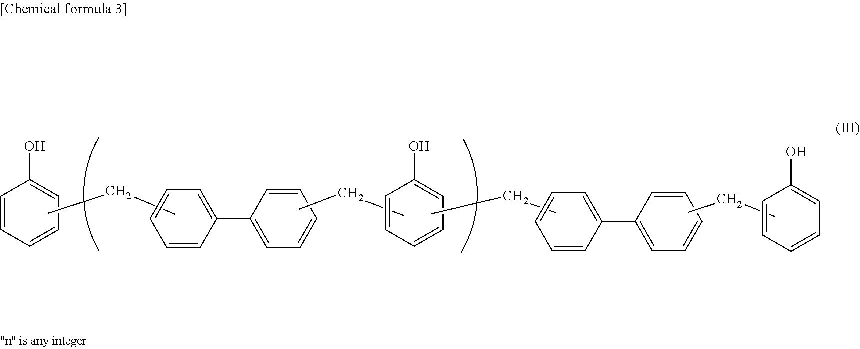

The repeating unit “n” of the biphenyl dimethylene type phenol resin represented by the above Formula (III) is not particularly limited, and is preferably from 1 to 12, more preferably from 2 to 8. If the average repeating unit “n” is less than the above lower limit, the heat resistance of the biphenyl dimethylene type phenol resin may decrease. If the average repeating unit “n” exceeds the above upper limit, the compatibility of the biphenyl dimethylene type phenol resin with another resins decrease, thereby, workability may decrease.

By using the above described cyanate ester resin (particularly, novolac type cyanate resin) and the arylalkylene type phenol resin in combination, it is possible to control the cross-linking density of the resin base material and insulating resin layer and easily control the reactivity of the resin composition upon curing.

The content of the phenol resin in the resin composition is not particularly limited, and is preferably from 1 to 55 wt %, more preferably from 5 to 40 wt %, with respect to the total weight of the resin composition. If the content is less than the above lower limit, the heat resistance of the resin base material and the insulating resin layer may decrease. If the content exceeds the above upper limit, the low-thermal expansion characteristics of the resin base material and the insulating resin layer may deteriorate.

The weight-average molecular weight of the phenol resin is not particularly limited, and is preferably from 4.0×10² to 1.8×10⁴, more preferably from 5.0×10² to 1.5×10⁴. If the weight-average molecular weight is less than the above lower limit, the resin base material (typically one containing glass fiber cloth) and the insulating resin layer may exhibit the tackiness. If the weight-average molecular weight exceeds the above upper limit, the impregnation of the resin composition into a glass base material (glass fiber cloth) upon producing the resin base material may decrease, thereby, a uniform product may not be obtained.

Further, if the multilayer printed wiring board is produced by using the cyanate ester resin (particularly, novolac type cyanate resin), the phenol resin (arylalkylene type phenol resin, particularly, biphenyl dimethylene type phenol resin), and the polyfunctional epoxy resin (arylalkylene type epoxy resin, particularly, biphenyl dimethylene type epoxy resin) in combination, it is possible to obtain particularly excellent dimensional stability.

In the present invention, the resin composition containing the cyanate ester resin used for the resin base material and insulating resin layer of the copper-clad laminate preferably contains an inorganic filler. Even though the printed wiring board and the semiconductor device provided with the resin base material (typically one containing glass fiber cloth) and the insulating resin layer are thin, the inorganic filler increases the mechanical strength of the printed wiring board and the semiconductor device. Thus, after semiconductor elements are mounted, the warpage upon applying thermal history by solder reflow, etc. is decreased more effectively, and further, the linear expansion coefficient decreases.

Examples of the inorganic filler include silicates such as talc, calcined clay, uncalcined clay, mica and glass; oxides such as titanic oxide, alumina, silica and fused silica; carbonates such as calcium carbonate, magnesium carbonate and hydrotalcite; hydroxides such as aluminum hydroxide, magnesium hydroxide and calcium hydroxide; sulfates or sulfites such as barium sulfate, calcium sulfate and calcium sulfite; borates such as zinc borate, barium metaborate, aluminum borate, calcium borate and sodium borate; nitrides such as aluminum nitride, boron nitride, silicon nitride and carbon nitride; and titanates such as strontium titanate and barium titanate. The inorganic filler may be used alone, or in combination of two or more kinds.

Among the above, silica is particularly preferable, and fused silica (particularly, spherical fused silica) is preferable from the viewpoint of excellent low-thermal expansion characteristics. The shape of silica includes crushed shape and spherical shape, and is used according to the purpose such as using spherical silica to decrease melting viscosity of the resin composition to secure impregnation into glass fiber woven fabric.

The average particle diameter of the inorganic filler is not particularly limited, and is preferably from 0.01 to 5.0 μm, more preferably from 0.1 to 2.0 μm. If the particle diameter of the inorganic filler is less than the above lower limit, the viscosity of the varnish increases, thus, the impregnation of the resin composition into glass fiber woven fabric may decrease. If the particle diameter of the inorganic filler exceeds the above upper limit, phenomenon such as precipitation of the inorganic filler in the varnish may be caused. The average particle diameter can be measured by, for example, particle size distribution analyzer (product name: LA-500; manufactured by HORIBA).

The inorganic filler is not particularly limited. An inorganic filler having a monodisperse average particle diameter (inorganic filler having a single average particle diameter or having a significantly narrow average particle diameter distribution), or an inorganic filler having a polydisperse average particle diameter (inorganic filler having a wide average particle diameter distribution) may be used. Further, the inorganic filler having a monodisperse and/or polydisperse average particle diameter may be used alone, or in combination of two or more kinds.

Further, spherical silica (particularly, spherical fused silica) having an average particle diameter of 5.0 μm or less is preferable, and spherical fused silica having an average particle diameter from 0.01 to 2.0 μm is particularly preferable. Thereby, the filling property of the inorganic filler improves.

The content of the inorganic filler is not particularly limited, and is preferably from 20 to 80 wt %, more preferably from 30 to 70 wt %, with respect to the total weight of the resin composition. By having the content of the inorganic filler within the above range, the resin base material and insulating resin layer are able to have particularly low thermal expansion and low water absorption.

The resin composition containing the cyanate ester resin is not particularly limited, and preferably contains a coupling agent. By using the coupling agent, the wettability of an interface between the cyanate ester resin and the inorganic filler improves. Thereby, it is possible to uniformly fix an insulating resin and inorganic filler on glass fiber woven fabric, and the heat resistance of the resin base material and insulating resin layer, particularly solder heat resistance after moisture absorption improves.

The coupling agent is not particularly limited. Specifically, it is preferable to use one or more coupling agents selected from epoxy silane coupling agents, cationic silane coupling agents, amino silane coupling agents, titanate coupling agents and silicone oil type coupling agents. Thereby, the wettability of an interface between the cyanate ester resin and the inorganic filler increases, and thus the heat resistance further improves.

The content of the coupling agent in the resin composition is not particularly limited since it depends on the surface area of the inorganic filler, and is preferably from 0.05 to 3 parts by weight, more preferably from 0.1 to 2 parts by weight, with respect to 100 parts by weight of the inorganic filler. If the content is less than the above lower limit, the inorganic filler cannot be sufficiently covered by the coupling agent, thus, the effect of improving the heat resistance of the resin base material and insulating resin layer may decrease. If the content exceeds the above upper limit, the curing reaction of the cyanate ester resin may be effected and the flexural strength, etc. of the resin base material and insulating resin layer may decrease.

The resin composition containing the cyanate ester resin may use a curing accelerator, if necessary. As the curing accelerator, known curing accelerators can be used. The examples include organometallic salts such as zinc naphthenate, cobalt naphthenate, tin octylate, cobalt octylate, bisacetylacetonatocobalt (II) and trisacetylacetonatocobalt (III); tertiary amines such as triethylamine, tributylamine and diazabicyclo[2,2,2]octane; imidazoles such as 2-phenyl-4-methylimidazole, 2-ethyl-4-ethylimidazole, 2-phenyl-4-methylimidazole, 2-phenyl-4-methyl-5-hydroxyimidazole and 2-phenyl-4,5-dihydroxyimidazole; phenol compounds such as phenol, bisphenol A and nonylphenol; organic acids such as acetic acid, benzoic acid, salicylic acid and p-toluenesulfonate; and the mixtures thereof. The curing accelerator including the derivatives thereof may be used alone, or two or more kinds including the derivative thereof may be used in combination.

Next, the semiconductor device will be described.

The semiconductor device can be produced by mounting semiconductor elements on the multilayer printed wiring board produced by the above described method. The mounting method and sealing method of the semiconductor elements are not particularly limited. For example, by means of semiconductor elements, a multilayer printed wiring board, and a flip chip bonder, etc., the positions of the electrode parts for connection and the solder bumps of the semiconductor elements on the multilayer printed wiring board are set. Then, solder bumps are heated to the temperature higher than the melting point by means of an IR reflow device, heated plate, or any other heating device, thereby, the multilayer printed wiring board and the solder bumps are joined by fusion. Then, the space between the multilayer printed wiring board and the semiconductor element is filled with a liquid encapsulating resin followed by curing. Thus, a semiconductor device is obtained.

The present invention is not particularly limited to the above embodiments, and modification and improvement within the range that the purpose of the present invention can be achieved are included in the present invention.

### EXAMPLES

Hereinafter, the present invention will be described further in detail with reference to examples, but is not limited to the following examples.

### Example 1

Copper foils on both surfaces of a copper-clad laminate (product name: ELC-9853; manufactured by Sumitomo Bakelite Co., Ltd.; 12 μm of copper foil) were overall etched using a ferric chloride solution, and thus obtained resin substrate was dipped in a 10% sulfuric acid aqueous solution for 2 minutes. Then, the obtained resin substrate was dipped in an alkaline cleaner (product name: THRU-CUP ACL-009; manufactured by C.Uyemura & Co., Ltd.) for 5 minutes, and further dipped in a palladium catalytic processing solution (product name: ALCUP Activator; manufactured by C.Uyemura & Co., Ltd.) for 5 minutes to adsorb a palladium catalyst. Next, the obtained resin substrate was dipped in a processing solution for palladium catalytic reduction (product name: ALCUP Reducer MAB; manufactured by C.Uyemura & Co., Ltd.) for 3 minutes to allow the palladium catalyst reduction. Thereafter, the obtained resin substrate was dipped in an electroless copper plating solution (product name: THRU-CUP PEA; manufactured by C.Uyemura & Co., Ltd.) for 15 minutes. Thereby, an electroless copper plating layer was formed.

After the obtained substrate, on which the electroless copper plating layer was formed, was subjected to heat treatment at 150° C. for 30 minutes, electrolytic copper plating was performed to form a copper layer having a thickness of 25 μm. Thereafter, heat treatment was performed at 200° C. for 60 minutes, thus, a double-sided copper plating substrate was obtained.

### Example 2

A double-sided copper plating substrate was obtained similarly as in Example 1 except that heat treatment was performed at 220° C. for 60 minutes after electrolytic copper plating.

### Example 3

A double-sided copper plating substrate was obtained similarly as in Example 1 except that heat treatment was not performed after electrolytic copper plating.

### Comparative Example 1

A double-sided copper plating substrate was obtained similarly as in Example 1 except that the obtained resin substrate was not dipped in the 10% sulfuric acid aqueous solution before dipping in the alkaline cleaner solution.

The properties were evaluated for the double-sided copper plating substrates obtained in Examples and Comparative examples. Results are shown in Table 1.

TABLE 1

| | Exam- | Exam- | Exam- | Comparative |
|---|---|---|---|---|
| | ple 1 | ple 2 | ple 3 | example 1 |
| Attachment of | good | good | good | not |
| electroless plating | | | | uniform |
| Peeling strength (kN/m) | 0.84 | 0.94 | 0.68 | |
| Hygroscopic solder heat | Pass | Pass | Pass | |
| resistance (PCT: 121° | | | | |
| C./2 hr; dipping: | | | | |
| 260° C./30 sec.) | | | | |

Peeling strength: the double-sided copper plating substrate was measured with reference to JIS C 481.

Hygroscopic solder heat resistance: a sample of 50 mm width grid was cut out from the obtained double-sided copper plating substrate. The half area of the sample was etched with reference to JIS C 6481 to produce a test piece. After processed by means of a pressure cooker at 121° C. for 2 hours, the sample was dipped in solder at 260° C. for 30 seconds. Then, presence of swelling was observed.

In Examples 1 to 3, the method of the present invention was used. In all Examples 1 to 3, the attachment of the electroless copper layer was uniform. Particularly, the peeling strength was high and hygroscopic heat resistance was excellent in Examples 1 and 2, which performed heat treatment after electrolytic copper plating. Peeling strength was slightly low in Example 3, which did not perform heat treatment after electrolytic copper plating, however, reliability was good because the hygroscopic heat test was performed without any problem.

To the contrary, the attachment of the electroless copper layer was not uniform after electroless copper plating step in Comparative example 1, which did not perform dipping in the 10% sulfuric acid aqueous solution. Thus, the electrolytic copper plating and characteristic evaluation were not performed.

From the above results, the effect of performing the acid treatment before each electroless copper plating step is clear, and the effect of performing the heat treatment after electrolytic copper plating for improving adhesion is also clear.

1. An electroless copper plating method for forming an electroless copper plating layer on a resin surface selected from a resin base material surface, an insulating resin layer surface, a through hole wall surface, a via hole bottom surface and a via hole wall surface using a palladium catalyst, wherein the surface to be plated is treated using an acid solution as pretreatment before performing alkaline degreasing, palladium adsorption, palladium reduction and electroless copper plating process.

2. The electroless copper plating method according to claim 1, wherein the acid solution is an aqueous solution containing sulfuric acid.

3. A method for producing a printed wiring board comprising the step of forming an electroless copper plating layer using the electroless copper plating method defined by claim 1.

4. A method for producing a printed wiring board comprising the step of forming an electroless copper plating layer on a resin base material surface, being obtained by etching a copper foil of a copper-clad laminate and transferring a roughened shape of the copper foil, using the electroless copper plating method defined by claim 1.

5. The method for producing the printed wiring board according to claim 3, wherein heat treatment is performed after electroless copper plating followed by electrolytic copper plating.

6. The method for producing the printed wiring board according to claim 5, wherein a temperature of the heat treatment is 200° C. or more.

7. The method for producing the printed wiring board according to claim 4, wherein a resin base material and/or an insulating resin layer of the copper-clad laminate is formed with a resin composition containing a cyanate ester resin and a polyfunctional epoxy resin.

8. A printed wiring board produced by the production method defined by claim 3.

9. A semiconductor device comprising a printed wiring board defined by claim 8 and a semiconductor element mounted on the printed wiring board.

10. The method for producing the printed wiring board according to claim 4, wherein heat treatment is performed after electroless copper plating followed by electrolytic copper plating.

11. The method for producing the printed wiring board according to claim 10, wherein a temperature of the heat treatment is 200° C. or more.

12. A printed wiring board produced by the production method defined by claim 4.

13. A semiconductor device comprising a printed wiring board defined by claim 12 and a semiconductor element mounted on the printed wiring board.
